(19) United States
(12) Patent Application Publication
(10) Pub. No.: US 2002/0130615 A1
(43) Pub. Date: Sep. 19, 2002

(54) Display panel

(75) Inventors: Keishi Saito, Saitama (JP); Sokichi Miyoshi, Saitama (JP); Takashi Nakano, Saitama (JP)

Correspondence Address: SUGHRUE MION, PLLC, 2100 Pennsylvania Avenue, N.W., Washington, DC, 20037-3213, US

(73) Assignee: PIONEER CORPORATION

(21) Appl. No.: 10/097,593

(22) Filed: Mar. 15, 2002

(30) Foreign Application Priority Data
Mar. 16, 2001 (JP) P2001-075524

(51) Int. Cl. H05B 33/00

(52) U.S. Cl. 313/506

(57) ABSTRACT

An organic EL display panel includes a plurality of organic EL elements 30 having a transparent electrode 11, at least one organic functional layer 12 containing a light-emitting layer of organic compound and a metallic electrode 13, which are successively stacked, respectively; a front-surface moisture-proofing film 10 which is kept in contact with the transparent electrode 11 to carry the plurality of organic EL elements 30 in plane; a rear-surface moisture-proofing film 14 which is kept in contact with the metallic electrode 13 to carry the plurality of organic EL elements 30 in plane; and sealing layers 15 which surround at least each of the organic functional layers 12 so that they are individually distinct from one another.

### BACKGROUND OF THE INVENTION

1. Field of the Invention

This invention relates to a display panel, particularly to an organic EL display panel using organic electrolum inescence (hereinafter referred to as organic EL) which emit light by application of an electric charge.

2. Description of the Related Art

In recent years, development of the organic electroluminescence (EL) panel prevails. The organic EL display panel includes a matrix display panel and a pattern display panel, etc. The matrix display panel has organic EL elements arranged in a matrix, each of the organic EL elements including a transparent electrode serving as an anode, an organic functional layer having a light emitting layer and a metallic electrode serving as a cathode, which are successively stacked on a transparent substrate, and each of the organic EL elements emitting light as a pixel to display a character or an image. The pattern display panel entirely emits light within a prescribed region. As the organic EL display panel, in place of an ordinary format using a glass as a transparent substrate, a film type organic EL display panel using resin or plastic as the transparent substrate has been proposed. Such a film type organic EL display panel, which is flexible, can make the display in a bent state.

The film type organic EL display panel, as long as it can be freely cut by scissors or the like, can serve as a light emitting body having various shapes and abruptly expands its application. However, as well known, the organic EL display panel is very easily affected by moisture. Concretely, the organic EL display panel has shortcomings that the interface between the metallic electrode and organic functional layer is peeled off owing to moisture and the organic functional layer itself changes in quality to generate a non-light-emitting portion, i.e. a dark spot. Therefore, the organic EL display panel presented a problem that even if it can be freely cut by the scissors or the like, moisture will invade from a section to deteriorate the display quality of the entire display portion greatly.

### SUMMARY OF THE INVENTION

This invention has been accomplished in view of the above problem. An object of this invention is to provide a display panel such as an organic EL display panel which does not deteriorate the display quality even when it is cut.

In order to achieve the above object, according to a first aspect of the invention, there is provided an organic EL display panel comprising: a plurality of organic EL elements having a first display electrode, at least one organic functional layer containing a light-emitting layer of organic compound and a second display electrode, which are successively stacked, respectively; a first resin substrate which is kept in contact with the first display electrode to carry the plurality of organic EL elements in plane; a second resin substrate which is kept in contact with the second display electrode to carry the plurality of organic EL elements in plane; and sealing layers which surround at least each of the organic functional layers so that they are individually distinct from one another.

According to a second aspect of the invention, in the organic EL display panel according to the first aspect, the organic EL elements have the first display electrode and second display electrode which are common to each of the organic EL elements.

According to a third aspect of the invention, in the organic EL display panel according to the first and second aspects, the first display electrode is connected to either one of an anode and cathode of a DC power source, and the second display electrode is connected to the other of the anode and cathode of the DC power source.

According to a fourth aspect of the invention, in the organic EL display panel according to the first and second aspects, the first display electrode is connected to a first bus electrode and the second display electrode is connected to a second bus electrode.

According to a fifth aspect of the invention, in the organic EL display panel according to the fourth aspect, the first bus electrode is formed on the first resin substrate, and the second bus electrode is formed on the second resin substrate.

According to a sixth aspect of the invention, in the organic EL display panel according to the fourth and fifth aspects, the first bus electrode is connected to either one of an anode and cathode of a DC power source, and the second bus electrode is connected to the other of the anode and the cathode of the DC power source.

According to a seventh aspect of the invention, in the organic EL display panel according to the fourth and fifth aspects, the first display electrode and the first bus electrode are connected by a connecting means formed in the first resin substrate, and the second display electrode and the second bus electrode are connected by another connecting means formed in the second resin substrate.

### BRIEF DESCRIPTION OF THE DRAWINGS

FIG. 1 is a sectional view of the main part of the organic EL element which constitutes an organic EL display panel according to the first embodiment;

FIG. 2 is a sectional view of the organic EL display panel 50 according to the first embodiment;

FIG. 3 is a plan view of the organic EL display panel according to the first embodiment;

FIG. 4 is a plan view of the organic EL display panel with a sketch to be cut out;

FIG. 5 is a plan view of the organic EL display panel which has been cut out;

FIG. 6 is a sectional view of the main part of the organic EL display panel when a battery is mounted in the vicinity of the outer periphery thereof;

FIG. 7 is a sectional view of the main part of the organic EL display panel when a battery is mounted in the vicinity of the center thereof; and

FIG. 8 is a sectional view of the main part of an organic EL display panel according to the second embodiment of this invention.

### DETAILED DESCRIPTION OF THE PREFERRED EMBODIMENTS

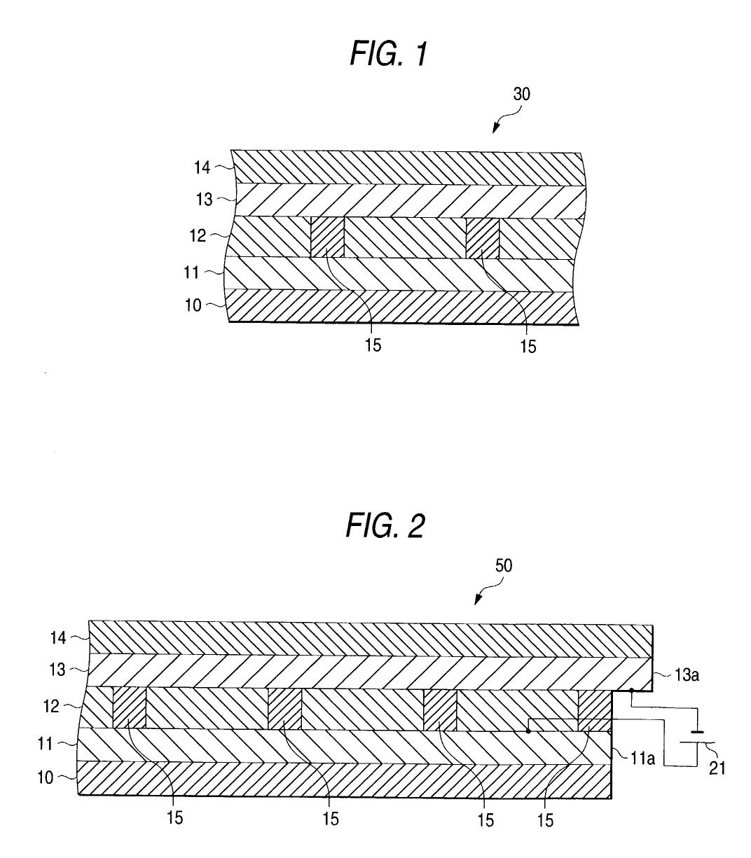

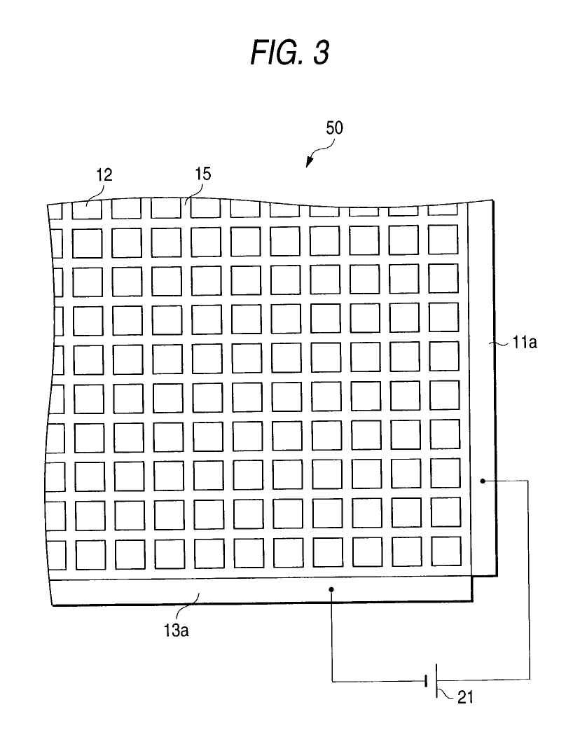

Now referring to FIGS. 1 to 3, an explanation will be given of the structure of an organic electroluminescence (EL) display panel 50 according to a first embodiment of this invention. However, this invention is not limited to the organic electroluminescence display panel but may be applied to any display panels. FIG. 1 is a sectional view of the main part of an organic EL element 30 which constitutes an organic EL display panel 50 according to this embodiment. FIG. 2 is a sectional view of an organic EL display panel 50. FIG. 3 is a plan view of the organic EL display panel 50.

As seen from FIG. 1, organic EL elements 30 which constitute an organic EL display panel 50 according to this embodiment, each includes a transparent electrode (first display electrode) 11 common to these organic EL elements, at least one organic functional layer 12 containing a light emitting layer of organic compound and a metallic electrode (second display electrode) 13 common to these organic EL elements, which are successively stacked, and further includes a front surface moisture-proofing film (first resin substrate) 10 which is kept in contact with the transparent electrode (first display electrode) 11 to carry the organic functional layer 12 , a rear surface moisture-proofing film (second resin substrate) 14 which is kept in contact with the metallic electrode (second display electrode) 13 to carry the organic functional layer 12, and a moisture sealing layer 15 which seals the perimeter of the organic functional layer 12.

The organic EL element 30 is manufactured by the process including following steps.

First, after the transparent electrode 11 which is made of iridium/tin oxide (ITO) is deposited on the front surface moisture-proofing film 10 by sputtering, a plurality of sealing layers 15 of ultraviolet rays setting resin are formed on the transparent electrode 11 are formed in a grid pattern by screen printing. Next, using a mask which is opened in the areas except the sealing layers 15 in the grid pattern, the organic functional layer 12 is formed in the sealing layers 15 by vacuum evaporation. The organic functional layer 12 is composed of a hole injection layer of copper phtd pattern by screen printing. Next, using a mask which is opened in the areas except the sealing layers 15 in the grid pattern, the organic functional layer 12 is formed in the sealing layers 15 by vacuum evaporation. The organic functional layer 12 is composed of a hole injection layer of copper phthalocyanine, a hole transporting layer of TPD (triphenylamine derivative) and a light emitting layer of Alq₃ (alumi chelate complex) and an electron injection layer of Li₂O(lithium oxide). By successively vacuum-evaporating these layers, a plurality of individual organic functional layers 12 which are distinct from one another are formed.

On the other hand, on the rear surface moisture-proofing film 14, Al aluminum is vacuum-evaporated to form the metallic electrode 13. The rear surface moisture-proofing film 14 is placed so that the sealing layers 15 and organic functional layers 12 are covered with the metallic electrode 13. Thereafter, when the sealing layers 15 are irradiated with ultra-violet rays, the sealing layers 15 are hardened with the ultra-violet rays so that the transparent electrode 11 and the sealing layers 15, and the metallic electrode 13 and the sealing layers 15 are sealed, respectively. In this way, a plurality of organic EL elements 30 in which the perimeters of the organic functional layers 12 are sealed by the sealing layers 15 are formed. Each of the organic EL elements 30 thus formed corresponds to a pixel of the organic EL display cell.

As seen from FIGS. 2 and 3, the organic EL display panel 50 manufactured by the process described above has a plurality of organic functional layers 12 in a grid pattern and sealing layers 15 surrounding the periphery of each of them. In the organic EL display panel 50, the transparent electrode 11 is formed in contact with the organic functional layer 12. For this reason, by forming the front surface moisture-proofing film 10 so that a portion of the transparent electrode 11 is exposed to provide a transparent electrode extending portion 11a, an anode of a DC power source can be connected to the transparent electrode extending portion 11a. Likewise, in the organic EL display panel 50, the metallic electrode 13 is formed in contact with the organic functional layer 12. For this reason,by forming the rear surface moisture-proofing film 14 so that a portion of the metallic electrode 13 is exposed to provide a transparent electrode extending portion 13a, a cathode of the DC power source can be connected to the metallic electrode extending portion 13a. Therefore, when a battery 21 is connected between the transparent electrode extending portion 11a and the metallic electrode extending portion 13a, the organic EL display panel 50 causes all the light emitting layers of the organic functional layers 12 to emit light.

As described above, the organic EL display panel 50 according to this embodiment, which employs the front surface moisture-proofing film 10 which is resin with excellent transparency in place of the ordinary glass substrate, can provide excellent flexibility. The organic EL display panel 50, in which the organic functional layers 12 corresponding to the individual pixels are individually formed so as to be surrounded by the sealing layers 15, can be cut for use. Namely, the areas except the cut portions can emit light with the display quality maintained without being affected by moisture from the outside.

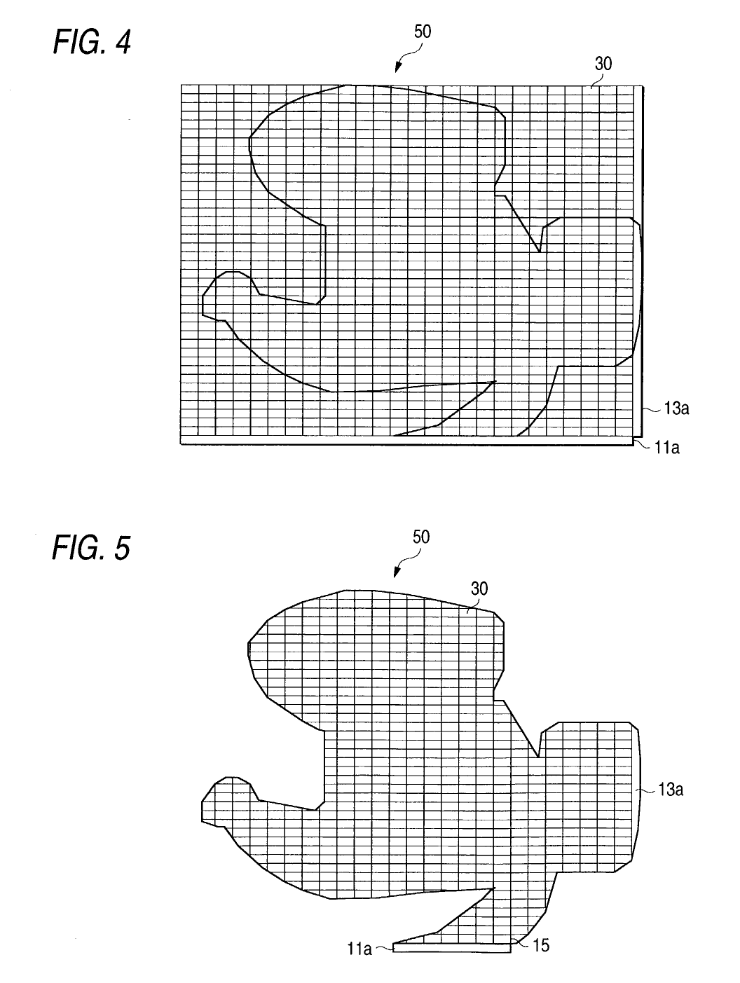

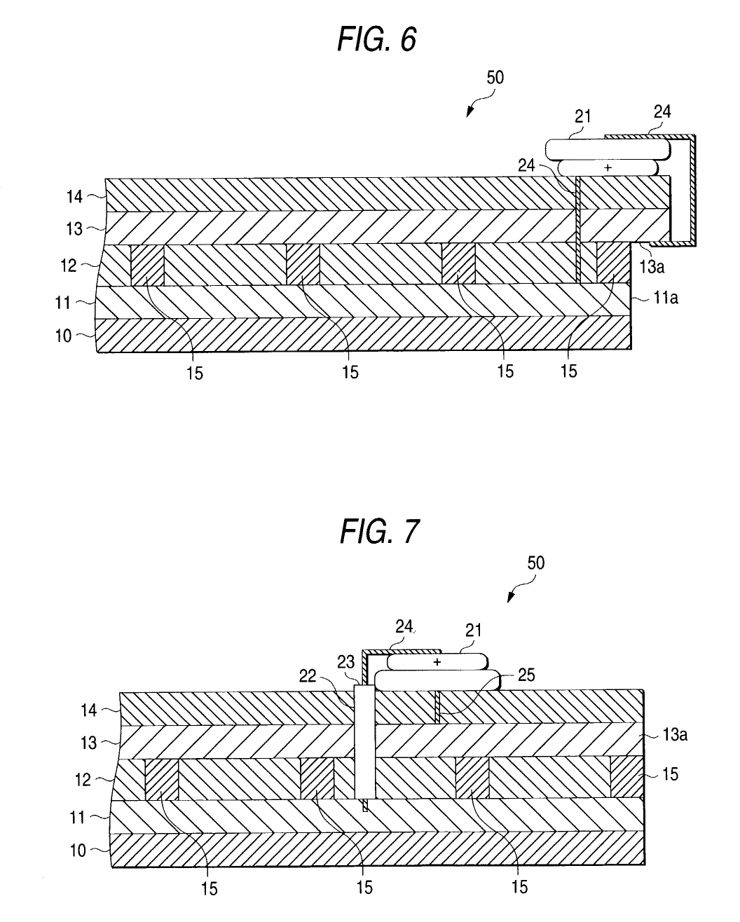

Now referring to FIGS. 4 to 7, an explanation will be given of a method of processing the organic EL display panel 50 and a method of supplying power. FIG. 4 is a plan view of the organic EL display panel 50 with a sketch to be cut out. FIG. 5 is a plan view of the organic EL display panel 50 which has been cut out. FIG. 6 is a sectional view of the main part of the organic EL display panel 50 when a battery 21 is mounted in the vicinity of the outer periphery thereof. FIG. 7 is a sectional view of the main part of the organic EL display panel 50 when a battery 21 is mounted in the vicinity of the center thereof.

As seen from FIG. 4, in the organic EL display panel 50, a plurality of organic EL elements 30 each surrounded in its four sides by the sealing layer 15 are arranged in a grid pattern, and a sketch having a desired shape is drawn on e.g. the surface moisture-proofing film 10. The sketch is cut out along the contour thereof. In this case, the sketch is drawn so that it partially includes the transparent electrode extending portion 11a and the metallic electrode extending portion 13a.

The organic EL display panel 50 is subjected to the cutting so as to include the transparent electrode extending portion 11a and metallic electrode extending portion 13a at its portions as shown in FIG. 5. In such an organic EL display panel 50, the organic EL elements 30 with the cut end faces exposed cannot emit light, whereas the other organic EL elements 30, which are surely sealed by the sealing layer 15 and hence not affected by moisture from the outside, can emit light. Thus, when power is supplied between the transparent electrode extending portion 11a and the metallic electrode extending portion 13a, the organic EL display panel 50 emits light as a portion 13a, the organic EL display panel 50 emits light as a

The organic EL display panel 50 can be used in a state where a battery 21 is mounted on the back. As seen from FIG. 6, as long as the battery 21 is mounted in the vicinity of the outer periphery on the rear surface moisture-proofing film 14, and the anode of the battery 21 and the transparent electrode extending portion 11a and the cathode of the battery 21 and the metald position in the organic EL display panel 50, an insulating spacer 23 is provided on the inner periphery of the wiring hole 22 and a wiring material 24 which passes through the spacer 23 connects the transparent electrode 11 to the anode of the battery 21. The battery 21 is fixed onto the rear surface moisture-proofing film 14. The cathode of the battery 21 and the metallic electrode 13 are connected to each other by a through-hole 25 which is a connecting means formed at a desired position within the rear surface moisture-proofing film 14. In this case, not via the extending portion, the anode of the battery 21 is directly connected to the wiring material 24 drawn inside the organic EL display panel 50. Likewise, not via the extending potion, the cathode of the battery 21 is also directly connected to the metallic electrode 13. This makes it unnecessary to use the extending potions. Such a battery 21, after the organic EL display panel 50 has been subjected to the cutting, is arranged at a desired position and used for connection. The battery 21 may be wired using a detachable socket. Attendantly, a switch for turning on/off the power of the battery 21 may be provided.

As described above, by subjecting the organic EL display panel 50 according to this embodiment as shown in FIGS. 6 and 7 to the cutting so as to have a desired shape and providing it with the battery 21, it can be caused to emit light as an interior decoration or animation character. In the organic EL display panel 50 shown in FIG. 6, the battery 21 is mounted in the vicinity on the outer periphery so that its anode and cathode are connected to the electrode extending portions through the wiring material drawn around the outside of the panel. This structure, in which the wiring material 24 is not drawn inside the panel, has no non-light emitting portion, and hence is simple. However, this structure must be cut out with a portion of the transparent electrode 11a and a portion of the metallic electrode extending portion 13a being partially left. Therefore, the shape to be cut out is limited somewhat. On the other hand, the organic EL display panel 50 shown in FIG. 7 provides a non-light-emitting portion at the area of the insulating spacer 23 formed inside the panel. However, if the battery 21 is located in the vicinity of the center of the panel, unlike the organic EL display panel shown in FIG. 6, the shape can be cut out with the outer periphery of the panel being not left partially. This increases the freedom of the shape to be cut out.

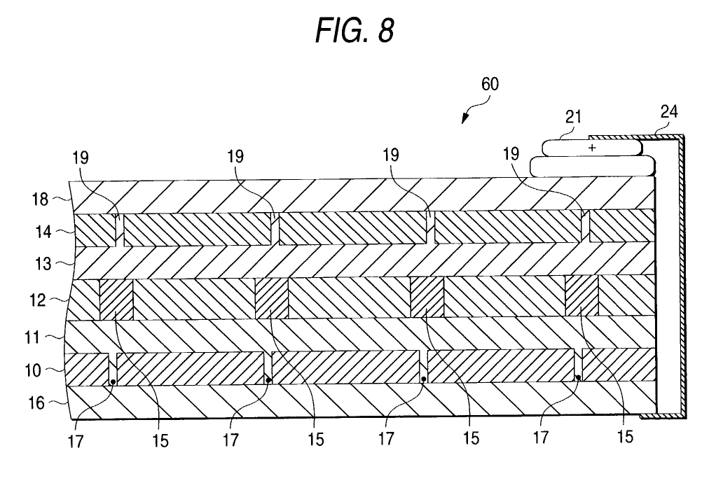

Referring to FIG. 8, an explanation will be given of an organic EL display panel 60 according to the second embodiment of this invention. FIG. 8 is a sectional view of the main part of the organic EL display panel 60 when the battery 21 is mounted in the vicinity on the outer periphery.

The organic EL display panel 60 according to this embodiment is different from the organic EL display panel 50 according to the first embodiment in that it is equipped with an anode bus electrode 16 and a cathode bus electrode 18. Specifically, in accordance with this embodiment, in the organic EL display panel 50 according to the first embodiment, a transparent anode bus electrode (first bus electrode) 16 is formed on the entire surface of the front surface moisture-proofing film 10 and is connected to the transparent electrode 11 through through-holes 17 which are the connecting means formed in the front surface moisture-proofing film 10 above the respective organic functional layers 12 or the sealing layers 15 surrounding them. Likewise, a cathode bus electrode (second bus electrode) 18 is formed on the entire surface of the rear surface moisture-proofing film 14 and is connected to the metallic electrode 13 through through-holes 19 formed in the rear surface moisture-proofing film 14 above the respective organic functional layers 12 or the sealing layers 15 surrounding them.

In the organic EL display panel 60 thus formed, unlike the organic EL display panel 50 according to the first embodiment, the battery can be connected to any position of the anode bus electrode 16 and cathode bus electrode 18 formed on the surfaces of the panel. Namely, since the anode bus electrode 16 and the cathode bus electrode 18 are formed on the entire front surface of the moisture-proofing film 10 and the entire rear surface of the moisture-proofing film 14, respectively, after the cutting, the anode and cathode of the battery can be connected to any positions of the anode bus electrode and the cathode bus electrode, respectively. Thus, unlike the orgaritten into the pixel electrodes of the pixel sections 101 as the video signals in synchronism with the scanning signals from the vertical drive circuit 130.

The pixel-potential control circuit 135 controls the video signal voltages written into the pixel electrodes in accordance with the control signals from the display control device 111. The gray scale voltages written into the pixel electrodes via the video signal lines 103 have some voltage difference with respect to the reference voltage on the counter electrode. The pixel-potential control circuit 135 varies the voltage difference between the pixel electrodes and the counter electrode by supplying a control signal to the pixel selections 101. The detail of the pixel-potential control circuit 135 will be explained subsequently.

The pixel section 101 in the liquid crystal display panel 100 in an embodiment of the present invention will be explained by reference circle not only the organic functional layers 12 but the entirety or part of the individual transparent electrodes and metallic electrodes which are in contact with the organic functional layer 12 and independent from one another. Thus, the organic EL display panel can have the structure composed of separate and distinct organic EL elements 30.

In accordance with this invention, the display quality is not deteriorated by the cutting. For this reason, the organic EL display panel can be provided which permits interior decoration or animation character designed by free conception to be made freely to emit light.

What is claimed is:

1. A display panel comprising:
a plurality of elements having a first display electrode, at least one functional layer containing a light-emitting layer of compound and a second display electrode, which are successively stacked, respectively;
a first resin substrate which is kept in contact with the first display electrode to carry said plurality of elements in plane;
a second resin substrate which is kept in contact with the second display electrode to carry said plurality of elements in plane; and
sealing layers which surround at least each of said functional layers so that they are individually distinct from one another.

2. The display panel according to claim 1, wherein said elements have the first display electrode and second display electrode which are common to each of the elements.

3. The display panel according to claim 1, wherein said first display electrode is connected to either one of an anode and cathode of a DC power source, and said second display electrode is connected to the other of said anode and cathode of the DC power source.

4. The display panel according to claim 1, wherein said first display electrode is connected to a first bus electrode and said second display electrode is connected to a second bus electrode.

5. The display panel according to claim 4, wherein said first bus electrode is formed on said first resin substrate, and said second bus electrode is formed on said second resin substrate.

6. The display panel according to claim 4, wherein said first bus electrode is connected to one of an anode and cathode of a DC power source, and said second bus electrode is connected to the other of the anode and the cathode of the DC power source.

7. The display panel according to claim 4, wherein said first display electrode and said first bus electrode are connected by a connecting means formed in said first resin substrate, and said second display electrode and said second bus electrode are connected by another connecting means formed in said second resin substrate.

8. The display panel according to claim 1, wherein said display panel is an organic electroluminescence panel.
